(19) United States
(12) Patent Application Publication
(10) Pub. No.: US 2007/0120472 A1
(43) Pub. Date: May 31, 2007

(54) Method for reducing the surface roughness of a thin layer of conductive oxides

(76) Inventors: Massimo Cocchi, Bologna (IT); Piergiulio Di Marco, Bologna (IT); Valeria Fattori, Bologna (IT); Gabriele Giro, Bologna (IT); Dalia Virgili, Bologna (IT); Alberto Garulli, Bologna (IT)

Correspondence Address: DARBY & DARBY P.C., P. O. BOX 5257, NEW YORK, NY, 10150-5257, US

(21) Appl. No.: 10/582,730

(22) PCT Filed: Dec. 12, 2003
(86) PCT No.: PCT/IT03/00813

§ 371 Date: Nov. 10, 2006

(51) Int. Cl. H01J 1/62; H01J 63/04

(52) U.S. Cl. 313/506

(57) ABSTRACT

A method for reducing the surface roughness of thin layers of conductive oxides for thin-layer opto-electronic devices envisages polishing with a finishing cloth and an abrasive compound, which has a basic pH and contains silica particles.

### TECHNICAL FIELD

The present invention relates to a method for reducing the surface roughness of a thin layer for thin-layer opto-electronic devices.

The present invention finds advantageous application in the field of organic electroluminescent devices (OLEDs), to which the ensuing treatment makes explicit reference without, however, this implying any loss of generality.

### BACKGROUND ART

Organic electroluminescent devices known as organic light emitting diodes (OLEDs) are light emitting devices which comprise one or more intermediate layers set between a cathode and an anode, which is usually constituted by a thin conductive layer made of indium and tin oxide (ITO) supported by a plate of glass. At least one of the intermediate layers comprises organic material.

The intermediate layers and the cathode and anode layers present in OLEDs are usually obtained via known techniques of spin coating and/or dipping, or else evaporation and/or high-vacuum cathodic sputtering.

Even though OLEDs form a subject of considerable interest for the industry, they still present a relatively limited durability. The relatively poor durability is linked to the appearance of dark spots.

Usually, to obtain OLEDs, the intermediate layers, which have an overall thickness normally comprised between 50 nm and 200 nm, are deposited on the thin ITO layer supported by the plate of glass, said layer having a thickness usually comprised between 50 nm and 250 nm.

Recently, it has been noted that one of the causes of the poor durability of OLEDs is the surface morphology of the anode.

In this regard, it is important to emphasize that studies carried out using atomic-force-microscopy techniques have shown that on the surface of commercially available ITO layers there are present defects constituted by aggregates having relatively large planar dimensions (from 1 μm to 5 μgm) and a height of approximately 100-200 nm. Said commercially available ITO has a mean roughness of approximately 2.4 nm and maximum difference in height between peak and trough of approximately 31 nm. Similar studies conducted on ITO layers obtained in the laboratory have shown similar mean roughnesses (approximately 2.4 nm) and maximum difference in height between peak and trough of approximately 54 nm.

The relatively high surface roughness of the thin ITO layer and the presence of differences in height between peak and trough comparable to the overall thickness of the intermediate layers, i.e., some tens of nanometres, appear to be one of the causes of the relatively low durability of OLEDs. The effects produced by the relatively high roughness could be multiple: for example, there could occur a non-uniform and very disorderly growth of the intermediate layers in contact with the ITO layer and/or an increase in the effective electrical field in the areas of the peaks. Said factors, in use, cause breakdown microdischarges and a rise in the local temperature due to the Joule effect, with a subsequent crystallisation of the organic material of the intermediate layers.

### DISCLOSURE OF INVENTION

The purpose of the present invention is to provide a method for reducing the surface roughness of a thin layer for thin-layer opto-electronic devices in order to cut down the drawbacks mentioned above and, consequently, increase the durability of thin-layer opto-electronic devices in a simple and economically advantageous manner.

According to the present invention, there is provided a method for reducing the surface roughness of a thin layer for thin-layer opto-electronic devices according to what is claimed in claim 1.

It is important to emphasize that here and throughout the text by “thin-layer opto-electronic device” is meant an opto-electronic device comprising at least one optically active layer (for example, a light-emitting or a light-sensitive layer), which has a thickness of between 1 nm and 300 nm and is set in contact of a thin layer comprising at least one conductive oxide.

In addition, hereinafter by “particles having substantially anti-aggregating properties” are meant particles that do not tend to form aggregates, i.e., do not exert on one another any form of attraction, for example, electrostatic attraction.

Finally, hereinafter by “diameter of a particle” is meant the diameter of a sphere equivalent to the particle. By “equivalent sphere” is meant the sphere having a diameter equal to the maximum length of the particle.

The present invention moreover relates to a thin layer for opto-electronic devices.

According to the present invention, a thin layer is provided as claimed in claim 8.

The present invention moreover relates to a thin-layer opto-electronic device.

According to the present invention a thin-layer opto-electronic device is provided as claimed in claim 16.

The present invention moreover relates to an organic electroluminescent device.

According to the present invention an organic electroluminescent device is provided as claimed in claim 18.

### BRIEF DESCRIPTION OF THE DRAWINGS

The invention will now be described with reference to the annexed drawings, which illustrate a non-limiting example of embodiment thereof, and in which:

FIG. 1 illustrates an organic electroluminescent device according to the present invention;

FIGS. 2, 5 and 3 represent topographic images (5×5 micron) obtained with an atomic-force microscope (Autoprobe CP Research manufactured by the company Veeco Instruments®), respectively, of a thin commercially available ITO layer, of a thin ITO layer prepared in the laboratory, and of a thin ITO layer treated according to the present invention; and

FIG. 4 illustrates the spectra of a thin ITO layer treated according to the present invention (dashed line) and of a commercially available ITO layer (continuous line).

### BEST MODE FOR CARRYING OUT THE INVENTION

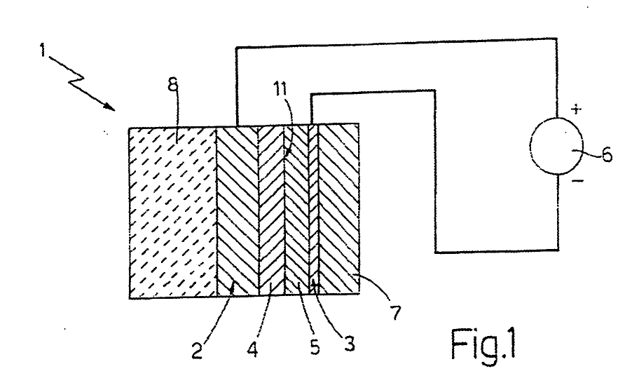

With reference to FIG. 1, designated as a whole by 1 is an organic electroluminescent device comprising an anode 2 and a cathode 3 separated from one another by two intermediate layers 4 and 5, each of which has a thickness of between 1 nm and 300 nm, in particular of substantially 60 nm.

The cathode 3 and the anode 2 are connected (in a known way and illustrated schematically) to an external current generator 6, which is designed to induce a potential difference between the cathode 3 and the anode 2.

The layer 4 comprises at least one organic material for transportation of positive charges and is designed to transfer electronic vacancies from the anode 2 to the layer 5. The layer 4 is set in contact with the anode 2 and the layer 5 so as to be set on the opposite side of the layer 5 with respect to the cathode 3.

The layer 5 comprises at least one organic material for transportation of negative charges, is designed to transfer electrons coming from the cathode 3 towards the layer 4 and is set in contact with the cathode 3 and on the opposite side of the layer 4 with respect to the anode 2.

The organic material for transportation of positive charges is designed to be combined with the organic material for transportation of negative charges so as to form exciplexes or electroplexes, which, by decaying from an electrically excited state are able to emit electromagnetic radiation or transfer their energy to luminescent molecules. For example, the organic material for transportation of positive charges is 4,4′, 4′″-Tri(N,N-diphenyl-amino)-triphenyl amine (TDATA), and the organic material for transportation of negative charges is 3-(4-diphenylyl)-4-phenyl-5-ter-butylphenyl-1,2,4-triazole (PBD).

The cathode 3 is provided with a layer, which is made of a material with a low work function, for example calcium, and is set in contact with a silver layer 7.

A glass substrate 8 is set on the opposite side of the anode 2 with respect to the layer 4 and provides a mechanical support to the anode 2, which comprises a relatively thin treated ITO layer, namely, one having a thickness of between 20 nm and 1000 nm, preferably of between 20 nm and 300 nm, in particular substantially of 80 nm. In this regard, it is important to emphasize that, since both the anode 2 and the glass substrate 8 are transparent, they enable passage of light.

The treated ITO layer presents morphological surface characteristics which are relatively high-quality, in particular, it presents differences in height between peak and trough of less than 28 nm and mean roughness of less than 1.7 nm.

According to preferred embodiments, the treated ITO layer presents differences in height between peak and trough of less than 22 nm, preferably of 15 nm; particularly preferred embodiments have difference in height between peak and trough of less than 12 nm, in particular of less than 8 nm.

Preferably, the mean roughness is of less than 1.0 nm.

Said morphological characteristics are obtained by means of a particular method for preparation of the anode 2. According to this method, an external surface of a thin ITO layer (obtainable by applying known methods), which has a thickness of between 20 nm and 1000 nm, preferably of between 20 nm and 300 nm, in particular of approximately 100 nm, coats the glass substrate 8, is polished by means of a polishing wheel, mounted on which is a polishing cloth soaked in an abrasive compound, so as to obtain a treated ITO layer.

The abrasive compound has particles having a diameter of between 5 nm and 150 nm. The action of the particles enables thin ITO layers having a relatively high-quality surface morphology to be obtained.

In this regard, it is important to emphasize that the choice of the sizes of the particles has a relatively high importance, in particular considering the relatively small thickness of the ITO layer and of the intermediate layers 4 and 5. The particles have dimensions such as to enable reduction of the roughness without damaging the thin ITO layer.

Preferably, the particles have anti-aggregating properties.

Preferably, the compound has a basic pH, and the particles are silica particles.

Note that silica particles in basic solution tend to be charged negatively and are consequently able to exert an electrostatic repulsion on one another.

The polishing cloths are usually classified into four families: rough-finishing cloths, semifinishing cloths, finishing cloths, and super-finishing cloths. Preferably, the polishing cloth used is a semifinishing cloth, a finishing cloth or a super-finishing cloth.

The polishing cloths can be of three different natures: woven cloths, non-woven cloths, and flocked cloths. Preferably the polishing cloth is a woven cloth.

Preferably the polishing cloth is made to rotate on the external surface of the thin ITO layer at a speed of between 400 r.p.m. and 600 r.p.m. applying a pressure of between 0.3 kg/cm² and 0.8 kg/cm² for between 10 and 20 seconds.

The device 1 is prepared by depositing in succession the layer 4, the layer 5, the cathode 3, and the silver layer 7, on top of one another, by sublimation in a high-vacuum evaporator and at a pressure of approximately 8×10⁻⁴ Pa, on the anode 2 obtained according to the method described.

Further characteristics of the present invention will emerge from the ensuing description of some non-limiting examples.

### EXAMPLE 1

This example describes polishing of a commercially available thin ITO layer.

A commercially available thin ITO layer, which has a thickness of approximately 100 nm and is supported by a plate of glass, was polished using an abrasive compound and a polishing cloth.

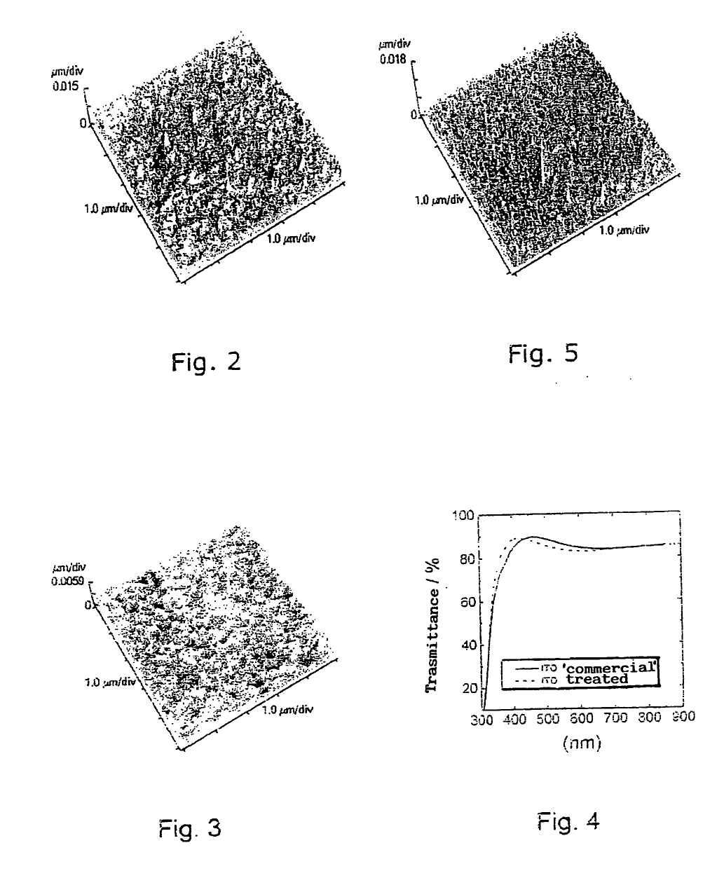

The commercially available thin ITO layer, the surface morphology of which is illustrated in FIG. 2, was formed by aggregates having planar dimensions of approximately 100-200 nm, with a maximum difference in height between peak and trough of approximately 31 nm and mean roughness of approximately 1.9 nm.

The polishing cloth was a woven finishing cloth and was made of synthetic fabric. The abrasive compound was obtained by diluting a colloidal solution, which comprised silica particles having a diameter of between 5 nm and 150 nm and dispersed in a basic solution of potassium hydroxide (the colloidal solution used is known by the commercial name Syton HT-50® and is produced by Dupont®), in deionized water in the proportions 1:8. The abrasive compound had a pH of between 10.5 and 11.3.

After the polishing cloth was soaked in the aforementioned compound, it was mounted on a polishing machine, which, after it reached the speed of 500 r.p.m., was applied to the commercially available ITO layer with a pressure of approximately 0.5 kg/cm² for approximately 15 seconds.

At this point, a treated thin ITO layer was obtained, the surface morphology of which is represented in FIG. 3, and which presented a maximum difference in height between peak and trough of approximately 6.7 nm and mean roughness of approximately 0.5 nm. The spectrum of transmittance of the treated ITO layer is represented with a dashed line in FIG. 4.

### EXAMPLE 2

This example describes polishing of a thin ITO layer prepared in the laboratory.

A thin ITO layer prepared in the laboratory, which had a thickness of approximately 100 nm and coated a plate of glass, was polished using an abrasive compound and a polishing cloth.

The thin ITO layer prepared in the laboratory, the surface morphology of which is illustrated in FIG. 5, had aggregates having planar dimensions of between approximately 50 nm and 100 nm, with a maximum difference in height between peak and trough of approximately 54 nm and a mean roughness of approximately 1.9 nm.

Polishing was carried out according to what is described in Example 1 so as to obtain the treated ITO layer substantially identical to the treated ITO layer described in Example 1.

### EXAMPLE 3

An organic electroluminescent device was prepared in the manner described in what follows.

A plate of glass coated with a thin ITO layer, which was treated according to Example 1 or Example 2, was cleaned by being dipped in a boiling solution of acetone and alcohol and by subsequently being laid for approximately thirty minutes in an ultrasound washing machine.

At this point, the following layers were deposited, in succession, one on top of the other, by sublimation in a high-vacuum evaporator and at a pressure of 8×10⁻⁴ Pa, on the coated plate of glass: a layer of 4,4′,4′″-Tri(N,N-diphenyl-amino)-triphenyl amine (TDATA) having the thickness of 60 nm; a layer of 3-(4-diphenylyl)-4-phenyl-5-ter-butylphenyl-1,2,4-triazole (PBD) having the thickness of 60 nm; a layer of calcium having the thickness of 25 nm; and a layer of silver having the thickness of 100 nm.

The ITO layer and the calcium layer were connected to an external generator.

1. A method for reducing the surface roughness of a thin layer for thin-layer opto-electronic devices, the thin layer comprising at least one conductive oxide and having a thickness of between 20 nm and 1000 nm, the method being characterized in that it comprises a polishing step of a mechanical type for polishing a surface of the thin layer using a polishing cloth and an abrasive compound, which includes particles having a diameter of between 5 nm and 150nm.

2. The method according to claim 1, in which said particles present substantially anti-aggregating properties.

3. The method according to claim 1, in which said particles are designed to exert an electrostatic repulsion on one another.

4. The method according to claim 1, in which said particles are silica particles and said compound has a basic pH, polishing being of a mechanical and chemical type.

5. The method according to claim 1, in which said polishing cloth is a woven cloth.

6. The method according to claim 1, in which said cloth is made to rotate on said surface at a speed of between 400 r.p.m. and 600 r.p.m. applying a pressure of between 0.3 kg/cm² and 0.8 kg/cm² for between 10 seconds and 20 seconds.

7. The method according to claim 1, in which the polishing cloth is chosen in the group consisting of:
semifinishing cloths,
finishing cloths, and
super-finishing cloths.

8. A thin layer for opto-electronic devices, the layer comprising at least one conductive oxide and being characterized in that it presents a difference in height between peak and trough of less than 28 nm and in that it has a thickness of between 20 nm and 1000 nm.

9. The layer according to claim 8, and presenting a difference in height between peak and trough of less than 22 nm.

10. The layer according to claim 8, and presenting a difference in height between peak and trough of less than 15 nm.

11. The layer according to claim 8, and presenting a difference in height between peak and trough of less than 12 nm.

12. The layer according to claim 8, and presenting a difference in height between peak and trough of less than 8 nm.

13. The layer according to claim 8, and having a mean roughness of less than 1.7 nmn.

14. The layer according to claim 8, and having a mean roughness of less than 1.0 nm.

15. The layer according to claim 8, and having a thickness of between 20 nm and 300 nm.

16. A thin-layer opto-electronic device comprising at least one optically active intermediate layer (4, 5); and a thin layer (2), which comprises at least one conductive oxide and is set in contact of the optically active intermediate layer (4, 5), the device being characterized in that the thin layer (2) is a thin layer according to claim 8.

17. The device according to claim 16, in which the optically active intermediate layer (4, 5) has a thickness of between 1 nm and 300 nm.

18. An organic electroluminescent device (OLED) comprising at least one cathode (3), at least one anode (2) and at least one optically active intermediate layer (4, 5) set between the anode and the cathode, said optically active intermediate layer (4, 5) comprising at least one organic material, the device (1) being characterized in that said anode (2) includes a thin layer according to claim 8.

19. The device according to claim 18, in which the optically active intermediate layer (4, 5) has a thickness of between 1 nm and 300 nm.
